(19) United States
(12) Patent Application Publication
(10) Pub. No.: US 2025/0172987 A1
(43) Pub. Date: May 29, 2025

(54) ELECTRONIC DEVICE AND OPERATING METHOD THEREOF

(71) Applicant: NANYA TECHNOLOGY CORPORATION, New Taipei City (TW)

(72) Inventor: Ting-Shuo Hsu, New Taipei City (TW)

(73) Assignee: NANYA TECHNOLOGY CORPORATION, New Taipei City (TW)

(21) Appl. No.: 18/519,079

(22) Filed: Nov. 27, 2023

(51) Int. Cl. G06F 1/3212; G06F 1/3237; G06F 1/3296

(52) U.S. Cl. CPC G06F 1/3212; G06F 1/3237; G06F 1/3296

(57) ABSTRACT

An electronic device and an operating method thereof are provided. The electronic device comprises a power up circuit, a delay circuit, and a plurality of power supply circuits. The power up circuit is configured to control a power up signal according to a power voltage. The delay circuit is configured to provide a plurality of enable signals by delaying the power up signal with different delay times. The plurality of power supply circuits are configured to be respectively activated by the plurality of enable signals.

### BACKGROUND

### 1. Technical Field

The disclosure generally relates to a device and a method, particular to an electronic device and an operating method thereof.

### 2. Description of Related Art

At initiations of an electronic device, keeping a supply voltage stable may keep a power up sequence correct, thereby keeping the electronic device functioning properly.

### SUMMARY

Accordingly, the disclosure is directed to an electronic device and the operating method which may keep the supply voltage stable at initiations.

The electronic device of the disclosure includes a power up circuit, a delay circuit, and a plurality of power supply circuits. The power up circuit is configured to control a power up signal according to a power voltage. The delay circuit is configured to provide a plurality of enable signals by delaying the power up signal with different delay times. The plurality of power supply circuits are configured to be respectively activated by the plurality of enable signals.

The operating method of the present disclosure includes: controlling, by a power up circuit, a power up signal according to a power voltage; providing, by a delay circuit, a plurality of enable signals by delaying the power up signal with different delay times; and activating the plurality of power supply circuit respectively by the plurality of enable signals.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates an electronic device according to some embodiments of the present disclosure.

FIG. 2A illustrates a schematic diagram of a delay circuit in accordance with some embodiments of the present disclosure.

FIG. 2B illustrates a schematic diagram of a delay circuit in accordance with some embodiments of the present disclosure.

FIG. 3A-3C illustrate various configurations of unit delay cells in accordance with some embodiments of the present disclosure.

FIG. 4 illustrates current curves of the power supply circuits drawn from the node supplying the power voltage VDD in accordance with some embodiments of the present disclosure.

FIG. 5 illustrates a flow chart of an operating method according to some embodiments of the present disclosure.

### DESCRIPTION OF THE EMBODIMENTS

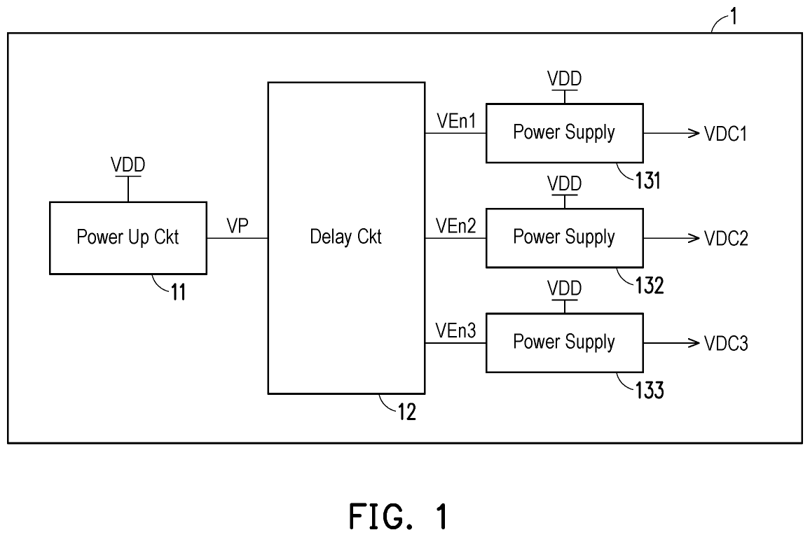

FIG. 1 illustrates an electronic device 1 according to some embodiments of the present disclosure. The electronic device 1 includes a power up circuit 11, a delay circuit 12, and power supply circuits 131-133. In brief, the power supply circuits 131-133 are configured to convert a power voltage VDD into a plurality of power supply voltages. At initiations of the electronic device 1, the power voltage VDD is gradually increased from a ground voltage. As the power voltage VDD increases, the power up circuit 11 keeps monitoring the power voltage VDD, so that the power up circuit 11 may inform power supply circuits 131-133 through a power up signal VP that the power voltage VDD is ready and reaches to a predetermined voltage level. The power supply circuits 131-133 may be respectively activated accordingly to convert the power voltage VDD to a corresponding power supply voltage. However, in order to maintain the power voltage VDD stable, especially at the initiation stage of the electronic device 1, and to avoid drawing large current by the power supply circuits 131-133 at the same time, the delay circuit 12 is added between the power up circuit 11 and the power supply circuits 131-133. Particularly, the delay circuit 12 is configured to delay the power up signal VP with different delay times, so that the delay circuit 12 may generate enable signals VEn1-VEn3 to activate the power supply circuit 131-133 at different time points, thereby avoiding the power supply circuits 131-133 to be turned on at the same time.

Specifically, the power up circuit 11 is configured to perform a power up sequence and compare the power voltage VDD with the predetermined voltage level. In some embodiments, the predetermined voltage level may be a voltage level selected from a range between 0.5V-0.9V. When the power up circuit 11 senses that the power voltage VDD is increased to be greater than the predetermined voltage, it means that the power voltage VDD may be supplied to some certain circuits in the electronic device 1 for performing the power up sequence, the power up circuit 11 may accordingly pull up the power up signal VP to an enabling voltage level to inform those circuits.

The delay circuit 12 is coupled to the power up circuit 11 and configured to generate the enable signals VEn1-VEn3 by delaying the power up signal VP with different delay times. By applying the different delay times to the power up signal VP to generate the enable signals VEn1-VEn3, rising edges of the enable signals VEn1-VEn3 may be properly separated. In some embodiments, the delay time inserted by the delay circuit 12 may be at nanosecond scale such as 20 ns, 50 ns, 100 ns, or at microsecond scale such as 15 us, 20 us, or other suitable time lengths depending on system requirements from and design concepts to the electronic device 1.

The power supply circuits 131-133 are configured to be respectively activated by the enable signals VEn1-VEn3 to convert the power voltage VDD to the power supply voltages VDC1-VDC3. In some embodiments, the power supply circuits 131-133 are coupled to a same node which supplies the power voltage VDD and respectively configured to convert the power voltage VDD to the power supply voltage at a proper voltage level such that corresponding circuit component inside the electronic device 1 may be supplied by those converted power supply voltages for operation. Specifically, since the enable signals VEn1-VEn3 are delayed by the different delay times, rising edges of the enable signals VEn1-VEn3 are separated, so the power supply circuits 131-133 are accordingly activated at different time points according to the rising edges of the enable signals VEn1-VEn3. As such, the power voltage VDD may be effectively kept stable by turning on the power supply circuits 131-133 sequentially and separately to avoid all power supply circuits 131-133 draw current from the node supplying the power voltage VDD at once. In some embodiments, each power supply circuit 131-133 may be a low-dropout (LDO) circuit or a DC-DC converter which may be utilized for converting one voltage level into another, such as rising or lowering the voltage level to another adequate voltage level, and stabilizing the voltage.

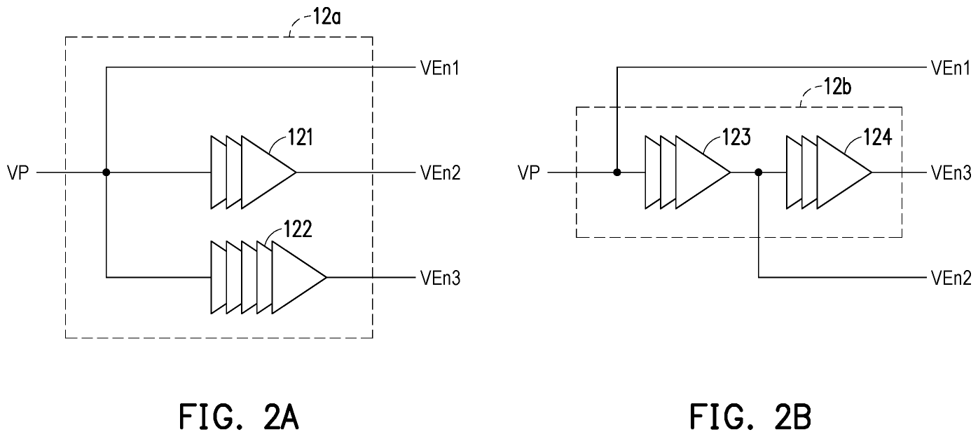

FIG. 2A illustrates a schematic diagram of a delay circuit 12a in accordance with some embodiments of the present disclosure. The delay circuit 12a in FIG. 2A may be applied in the electronic device 1 in FIG. 1 to replace the delay circuit 12. The delay circuit 12a is configured to delay the power up signal VP by the different delay times and generate the enable signals VEn1-VEn3. Specifically, the delay circuit 12a includes delay chains 121, 122. Further, the delay circuit 12a couples the power up circuit 11 to the power supply circuit 131 through metal wire, and couples the power up circuit 11 to the power supply circuits 132, 133 through the delay chains 121, 122. The metal wire between the power up circuit 11 and the power supply circuit 131 provides a little or ignorable delay time compared to that of the delay chains 121, 122 and the delay chain 121 provides a shorter delay time than the delay chain 122. As such, the delay circuit 12a may properly delay the power up signal VP by the different delay times and generate the enable signals VEn1-VEn3.

Further, the delay chains 121, 122 each include at least one unit delay cell coupled in series between the power up circuit 11 and their respective corresponding power supply circuit 132, 133. Each unit delay cell is configured to delay the input signal for a predetermined delay time and output the delayed signal. The number of unit delay cells in each delay chain may be determined according to a structure of the deployed unit delay cell and a length of the delay time required by the electronic device 1.

FIG. 2B illustrates a schematic diagram of a delay circuit 12b in accordance with some embodiments of the present disclosure. The delay circuit 12b in FIG. 2B may be applied in the electronic device 1 in FIG. 1 to replace the delay circuit 12. The delay circuit 12b in FIG. 2B functions similarly to the delay circuit 12a in FIG. 2A which may delay the power up signal VP by different the delay times to generate the enable signals VEn1-VEn3. More particularly, the delay circuit 12b includes delay chains 123, 124 coupled in series after the power up circuit 11. In some aspect, the delay circuit 12b may be regarded as a huge delay chain receiving the power up signal VP, and the enable signals VEn1-VEn3 may be outputted different stages of the unit delay cells in the delay chain formed by the delay chains 123, 124. In the exemplary embodiment of FIG. 2B, the power up signal VP is directly provided as the enable signal VEn1 through metal wire connection. The enable signal VEn2 is generated after the power up signal VP is delayed by the delay chain 123, and the enable signal VEn2 is generated after the power up signal VP is delayed by the delay chains 123, 124. As such, it may be guaranteed that the enable signals VEn1-VEn3 switched to the enabling voltage level according to a predetermined sequence. Further, by properly handling the delay times of the delay chains 123, 124, the power supply circuits 131-133 may be preferably activated at separate time points, keeping the power voltage VDD stable. Similarly, the number of unit delay cells in the delay chains 123, 124 may be determined according to a structure of the deployed unit delay cell and a length of the delay time required by the electronic device 1.

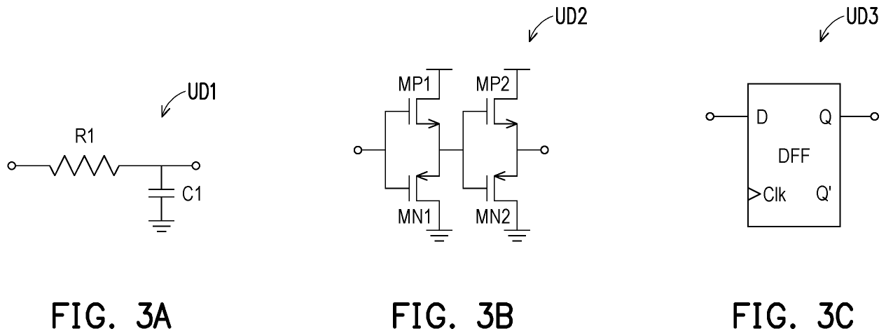

FIG. 3A-3C illustrate various configurations of unit delay cells UD1-UD3 in accordance with some embodiments of the present disclosure. In FIG. 3A, the unit delay cell UD1 may include a resistor R1 and a capacitor C1. The resistor R1 is coupled between an input terminal and an output terminal of the unit delay cell UD1, and the capacitor C1 is coupled between the output terminal of the unit delay cell UD1 and a ground voltage, so that the delay time provided by the unit delay cell UD1 may be determined based on the resistance and capacitance of the resistor R1 and the capacitor C1.

More particularly, when the unit delay cell UD1 is adopted in the delay chains 121, 122 in FIGS. 2A, each delay chain may include only one unit delay cell UD1 since the unit delay cell UD1 may provide different delay times by modifying the resistance and/or capacitance of the resistor R1 and the capacitor C1. However, it is also possible for the delay chains 121, 122 to dispose more than one unit delay cells UD1 inside, which allows each unit delay cell UD1 to have the same structure and generate the same length of delay time, thereby reducing design difficulty of the delay circuit 12a. Similarly, the same concept may be applied when the unit delay cell UD1 is adopted in the delay chains 123, 124 in FIGS. 2B, such that the delay chains 123, 124 may include the same or different numbers of the unit delay cell UD1 to generate the required delay time.

In FIG. 3B, the unit delay cell UD2 may include transistors MP1, MP2, MN1, MN2 forming two inverters coupled in series between the input and output terminals of the unit delay cell UD2. The delay time of the unit delay cell UD2 may be determined according to the transistor size. Therefore, when the unit delay cell UD2 is utilized in the delay chains 121-124, different delay times may be realized by the delay chains 121-124 with merely one unit delay cell UD2 disposed inside. However, it is also possible for the delay chains 121-124 to dispose more than one unit delay cells UD1 each with the same size and the same delay time, reducing design complexity of the delay circuit 12b.

In FIG. 3C, the unit delay cell UD3 may be a D flip-flop (DFF). The unit delay cell UD3 is configured to provide an input data received from an input terminal to an output terminal as a clock signal triggers. Therefore, since the delay time generated by each the unit delay cell UD3 is equivalent, different delay times may be achieved by different numbers of the unit delay cells UD3 in series when the unit delay cell UD3 is applied in the delay chains 121-124.

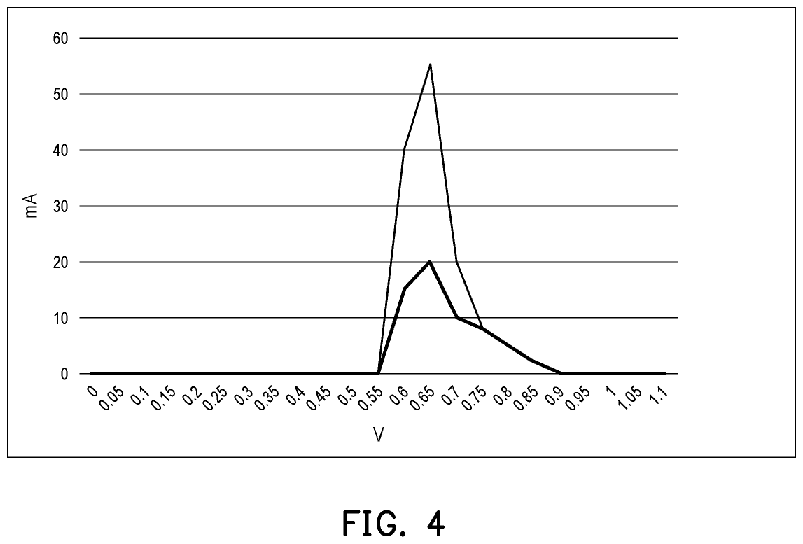

FIG. 4 illustrates current curves L41, L42 of the power supply circuits 131-133 drawn from the node supplying the power voltage VDD in accordance with some embodiments of the present disclosure. Specifically, the curve L41 corresponds to the current of the power supply circuits 131-133 being activated at the same time, and the curve L42 corresponds to the current spike of the power supply circuits 131-133 being activated separately. As can be seen in FIG. 4, as the power voltage increases and reaches the predetermined voltage level, for example 0.55V, the power up circuit 11 switches the power up signal VP to the enabling voltage level. In an exemplary embodiment that the power up signal VP is directly provided to the power supply circuits 131-133 without the delay circuit 12, all the power supply circuits 131-133 are activated at the same time, causing a large current occurred on the curve L41. In comparison, when there is the delay circuit 12 disposed between the power up circuit 11 and the power supply circuits 131-133 to delay the power up signal VP by the different delay times, initiations of the power supply circuits 131-133 may be effectively separated to avoid large current drawn from the node supplying the power voltage VP, causing a lower current spike on the curve L42. Therefore, the electronic device 1 may effectively maintain the power voltage VP stable by delaying the power up signal VP with different the delay times using the delay circuit 12.

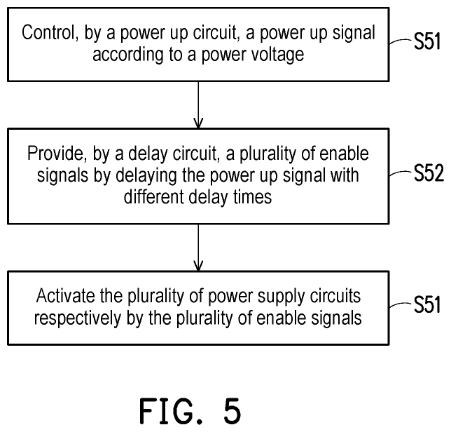

FIG. 5 illustrates a flow chart of an operating method according to some embodiments of the present disclosure. The operating method in FIG. 5 may be utilized to operate the electronic device 1 in FIG. 1. Specifically, the operating method includes steps S51-S53.

In step S51, a power up signal VP is controlled by the power up circuit 11 according to a power voltage VDD. Specifically, the power up circuit 11 is configured to perform a power up sequence and compare the power voltage VDD with the predetermined voltage level. In some embodiments, the predetermined voltage level may be a voltage level selected from a range between 0.5V-0.9V. When the power up circuit 11 senses that the power voltage VDD is increased to be greater than the predetermined voltage, it means that the power voltage VDD may be supplied to some certain circuits in the electronic device 1 for performing the power up sequence, the power up circuit 11 may accordingly pull up the power up signal VP to an enabling voltage level to inform those circuits to start their initiations.

In step S52, a plurality of enable signals by delaying the power up signal with different delay times. Specifically, the delay circuit 12 is coupled to the power up circuit 11 and configured to generate the enable signals VEn1-VEn3 by delaying the power up signal VP with different delay times. By applying the different delay times to the power up signal VP, rising edges of the enable signals VEn1-VEn3 may be properly separated. In some embodiments, the delay time inserted by the delay circuit 12 may be at nanosecond scale such as 20 ns, 50 ns, 100 ns, or at microsecond scale such as 15 us, 20 us, or other suitable time lengths depending on system requirements from and design concepts to the electronic device 1.

In step S53, a plurality of power supply circuits 131-133 are respectively activated by the plurality of enable signals VEn1-VEn3. Specifically, the power supply circuits 131-133 are configured to be respectively activated by the enable signals VEn1-VEn3 to convert the power voltage VDD to the power supply voltages VDC1-VDC3. In some embodiments, the power supply circuits 131-133 are coupled to a same node which supplies the power voltage VDD and respectively configured to convert the power voltage VDD to the power supply voltage at a proper voltage level such that corresponding circuit component inside the electronic device 1 may be supplied by those converted power supply voltages for operation. Specifically, since the enable signals VEn1-VEn3 are delayed by the different delay times, rising edges of the enable signals VEn1-VEn3 are separated, so the power supply circuits 131-133 are accordingly activated at different time points according to the rising edges of the enable signals VEn1-VEn3. As such, the power voltage VDD may be effectively kept stable by turning on the power supply circuits 131-133 sequentially and separately to avoid all power supply circuits 131-133 draw current from the node supplying the power voltage VDD at once. In some embodiments, each power supply circuit 131-133 may be a low-dropout (LDO) circuit or a DC-DC converter which may be utilized for converting one voltage level into another, such as rising or lowering the voltage level to another adequate voltage level, and stabilizing the voltage.

In summary, the electronic device and the operating method may effectively separate initiations of the power supply circuits by disposing the delay circuit to delay the power up signal with the different delay times. As such, initiations of the power supply circuits may be separated to avoid large current drawn from the node supplying the power voltage, stabilizing the power voltage.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a power up circuit, configured to control a power up signal according to a power voltage;
a delay circuit, configured to provide a plurality of enable signals by delaying the power up signal with different delay times; and
a plurality of power supply circuits, configured to be respectively activated by the plurality of enable signals.

2. The electronic device of claim 1, wherein the power up circuit is configured to switch the power up signal to an enabling voltage level when the power up circuit senses that the power voltage rises to be greater than a predetermined voltage level.

3. The electronic device of claim 2, wherein the predetermined voltage level is selected from a range between 0.5V-0.9V.

4. The electronic device of claim 1, wherein each of the power supply circuit is activated by the corresponding enable signal to convert the power voltage to a power supply voltage.

5. The electronic device of claim 1, wherein at least one of the power supply circuits is a low dropout (LDO) circuit or a DC-DC converter.

6. The electronic device of claim 1, wherein the delay circuit comprises a plurality of delay chains, and each of the delay chain comprises at least one unit delay cell coupled in series between the power up circuit and the corresponding power supply circuit.

7. The electronic device of claim 6, wherein each of the unit delay cell is a RC delay cell, a buffer, an inverter, or a flip-flop.

8. The electronic device of claim 7, wherein each of the unit delay cell is the buffer or the inverter, and sizes of the unit delay cells are different.

9. The electronic device of claim 6, wherein each of the unit delay cell provides a same unit delay time, and the plurality of delay chains comprise different numbers of the unit delay cells.

10. The electronic device of claim 1, wherein the delay circuit comprises a delay chain coupled to the power up circuit, the delay chain comprises a plurality of unit delay cells coupled in series, and the enable signals are outputted by different stages of the unit delay cells in the delay chain.

11. An operating method of an electronic device, the electronic device comprising a power up circuit, a delay circuit, and a plurality of power supply circuits, the operating method comprising:
controlling, by the power up circuit, a power up signal according to a power voltage;
providing, by the delay circuit, a plurality of enable signals by delaying the power up signal with different delay times; and
activating the plurality of power supply circuit respectively by the plurality of enable signals.

12. The operating method of claim 11, comprising switching, by the power up circuit, the power up signal to an enabling voltage level when it is sensed that the power voltage rises to be greater than a predetermined voltage level.

13. The operating method of claim 12, wherein the predetermined voltage level is selected from a voltage level between 0.5V-0.9V.

14. The operating method of claim 11, comprising activating each of the power supply circuit by the corresponding enable signal to convert the power voltage to a power supply voltage.
